(19) United States
(12) Patent Application Publication
(10) Pub. No.: US 2016/0309618 A1
(43) Pub. Date: Oct. 20, 2016

(54) LIQUID COOLING HEAT DISSIPATION STRUCTURE AND METHOD OF MANUFACTURING THE SAME

(71) Applicant: COOLER MASTER CO., LTD., New Taipei City (TW)

(72) Inventors: SHUI-FA TSAI, NEW TAIPEI CITY (TW); CHANG-HAN TSAI, NEW TAIPEI CITY (TW)

(21) Appl. No.: 14/689,131

(22) Filed: Apr. 17, 2015

(51) Int. Cl. H05K 7/20; B23P 15/26

(52) U.S. Cl. CPC H05K 7/20218; H05K 7/20409; B23P 15/26

(57) ABSTRACT

A liquid cooling heat dissipation structure includes a single heat conduction module and an assembly liquid supply module. The single heat conduction module includes a heat-conducting substrate contacting a heat generation source, a plurality of heat-conducting fins fixedly disposed on the heat-conducting substrate, a heat-conducting fluid-splitting board fixedly disposed on the heat-conducting substrate, and a heat-conducting fluid-conducting board fixedly disposed on the heat-conducting fluid-splitting board. The assembly liquid supply module includes an external cover body detachably disposed on the heat-conducting substrate and a rotary component detachably disposed between the external cover body and the heat-conducting fluid-conducting board. Therefore, cooling liquid passes through at least one liquid inlet and flows into the external cover body to contact the single heat conduction module by driving the rotary component, so that heat transmitted from the heat generation source to the single heat conduction module is absorbed by the cooling liquid.

### BACKGROUND OF THE INVENTION

1. Field of the Invention

The instant disclosure relates to a liquid cooling heat dissipation structure and a method of manufacturing the same, and more particularly to a liquid cooling heat dissipation structure and a method of manufacturing the same for increasing its heat dissipation efficiency.

2. Description of Related Art

A water block heat-dissipating structure of the prior art includes a seat body and a seal cover body. The seat body has a plurality of heat-dissipating fins formed thereon, and a bottom portion of the seat body contacting a heat-generating source. In addition, the seal cover body is used to seal and cover the seat body. The seal cover body further has a water inlet and a water outlet. When the bottom portion of the seat body contacts a heat-generating source, heat is transmitted from the heat-generating source to the heat-dissipating fins. In addition, the heat of the first heat-dissipating fins can be guided away quickly by cooling liquids that circulate between the water inlet and the water outlet.

### SUMMARY OF THE INVENTION

One aspect of the instant disclosure relates to a liquid cooling heat dissipation structure and a method of manufacturing the same for increasing its heat dissipation efficiency by using a single heat conduction module.

One of the embodiments of the instant disclosure provides a liquid cooling heat dissipation structure, comprising: a single heat conduction module and an assembly liquid supply module. The single heat conduction module includes a heat-conducting substrate contacting a heat generation source, a plurality of heat-conducting fins fixedly disposed on the heat-conducting substrate, a heat-conducting fluid-splitting board fixedly disposed on the heat-conducting substrate to cover the heat-conducting fins, and a heat-conducting fluid-conducting board fixedly disposed on the heat-conducting fluid-splitting board, wherein the heat-conducting fluid-splitting board has a first fluid-conducting opening and a second fluid-conducting opening communicated with the first fluid-conducting opening through a first receiving space, and the heat-conducting fluid-splitting board has a first fluid-splitting opening communicated with the second fluid-conducting opening through a second receiving space and a second fluid-splitting opening communicated with the first fluid-splitting opening through a third receiving space. The assembly liquid supply module includes an external cover body detachably disposed on the heat-conducting substrate and a pump detachably disposed on the external cover body, wherein the heat-conducting fins, the heat-conducting fluid-splitting board, and the heat-conducting fluid-conducting board are received inside the external cover body, and the external cover body has at least one liquid inlet communicated with the first liquid-conducting opening through a fourth receiving space and at least one liquid outlet communicated with the second fluid-splitting opening.

More precisely, when heat generated by the heat generation source is transmitted to the heat-conducting substrate, the heat-conducting fins, the heat-conducting fluid-splitting board, and the heat-conducting fluid-conducting board of the single heat conduction module, cooling liquid passes through the at least one liquid inlet and flows into the external cover body to contact the heat-conducting substrate, the heat-conducting fins, the heat-conducting fluid-splitting board, and the heat-conducting fluid-conducting board by driving the pump, so that the heat that has been transmitted to the heat-conducting substrate, the heat-conducting fins, the heat-conducting fluid-splitting board, and the heat-conducting fluid-conducting board of the single heat conduction module is absorbed by the cooling liquid.

Another one of the embodiments of the instant disclosure provides a liquid cooling heat dissipation structure, comprising: a single heat conduction module and an assembly liquid supply module. The single heat conduction module includes a heat-conducting substrate contacting a heat generation source, a plurality of heat-conducting fins fixedly disposed on the heat-conducting substrate, a heat-conducting fluid-splitting board fixedly disposed on the heat-conducting substrate to cover the heat-conducting fins, and a heat-conducting fluid-conducting board fixedly disposed on the heat-conducting fluid-splitting board. The assembly liquid supply module includes an external cover body detachably disposed on the heat-conducting substrate and a rotary component detachably disposed between the external cover body and the heat-conducting fluid-conducting board, wherein the heat-conducting fins, the heat-conducting fluid-splitting board, and the heat-conducting fluid-conducting board are received inside the external cover body, and the external cover body has at least one liquid inlet and at least one liquid outlet. Therefore, cooling liquid passes through the at least one liquid inlet and flows into the external cover body to contact the single heat conduction module by driving the rotary component, so that heat transmitted from the heat generation source to the single heat conduction module is absorbed by the cooling liquid.

Yet another one of the embodiments of the instant disclosure provides a method of manufacturing a liquid cooling heat dissipation structure, comprising: manufacturing a single heat conduction module, wherein the single heat conduction module includes a heat-conducting substrate contacting a heat generation source, a plurality of heat-conducting fins fixedly disposed on the heat-conducting substrate, a heat-conducting fluid-splitting board fixedly disposed on the heat-conducting substrate to cover the heat-conducting fins, and a heat-conducting fluid-conducting board fixedly disposed on the heat-conducting fluid-splitting board; and then detachably assembling an assembly liquid supply module on the single heat conduction module, wherein the assembly liquid supply module includes an external cover body detachably disposed on the heat-conducting substrate and a rotary component detachably disposed between the external cover body and the heat-conducting fluid-conducting board, wherein the heat-conducting fins, the heat-conducting fluid-splitting board, and the heat-conducting fluid-conducting board are received inside the external cover body, and the external cover body has at least one liquid inlet and at least one liquid outlet. Therefore, cooling liquid passes through the at least one liquid inlet and flows into the external cover body to contact the single heat conduction module by driving the rotary component, so that heat transmitted from the heat generation source to the single heat conduction module is absorbed by the cooling liquid.

More precisely, the step of manufacturing the single heat conduction module further comprises: forming the plurality of heat-conducting fins on the heat-conducting substrate; riveting the heat-conducting fluid-conducting board on the heat-conducting fluid-splitting board, wherein the heat-conducting fluid-splitting board has a plurality of riveting holes; and then welding the heat-conducting fluid-splitting board with the heat-conducting fluid-conducting board on the heat-conducting substrate, wherein a surrounding welding layer is formed between the heat-conducting fluid-splitting board and the heat-conducting substrate.

Therefore, when heat generated by the heat generation source is transmitted to the heat-conducting substrate, the heat-conducting fins, the heat-conducting fluid-splitting board, and the heat-conducting fluid-conducting board of the single heat conduction module, cooling liquid passes through the at least one liquid inlet and flows into the external cover body to contact the heat-conducting substrate, the heat-conducting fins, the heat-conducting fluid-splitting board, and the heat-conducting fluid-conducting board by driving the pump, so that the heat that has been transmitted to the heat-conducting substrate, the heat-conducting fins, the heat-conducting fluid-splitting board, and the heat-conducting fluid-conducting board of the single heat conduction module is absorbed by the cooling liquid so as to increase the heat dissipation efficiency of the liquid cooling heat dissipation structure.

To further understand the techniques, means and effects of the instant disclosure applied for achieving the prescribed objectives, the following detailed descriptions and appended drawings are hereby referred to, such that, and through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a perspective, exploded, schematic view of the liquid cooling heat dissipation structure according to the instant disclosure;

FIG. 2 shows another perspective, exploded, schematic view of the liquid cooling heat dissipation structure according to the instant disclosure;

FIG. 3 shows a perspective, assembly, schematic view of the liquid cooling heat dissipation structure according to the instant disclosure;

FIG. 4 shows a cross-sectional view taken along the section line A-A of FIG. 3;

FIG. 5 shows an enlarged, schematic view taken on part A of FIG. 4;

FIG. 6 shows a cross-sectional view taken along the section line B-B of FIG. 3;

FIG. 7 shows a cross-sectional view taken along the section line C-C of FIG. 3; and

FIG. 8 shows a flowchart of the method of manufacturing a liquid cooling heat dissipation structure according to the instant disclosure.

### DETAILED DESCRIPTION OF THE PREFERRED EMBODIMENTS

The embodiments of “a liquid cooling heat dissipation structure and a method of manufacturing the same” of the instant disclosure are described. Other advantages and objectives of the instant disclosure can be easily understood by one skilled in the art from the disclosure. The instant disclosure can be applied in different embodiments. Various modifications and variations can be made to various details in the description for different applications without departing from the scope of the instant disclosure. The drawings of the instant disclosure are provided only for simple illustrations, but are not drawn to scale and do not reflect the actual relative dimensions. The following embodiments are provided to describe in detail the concept of the instant disclosure, and are not intended to limit the scope thereof in any way.

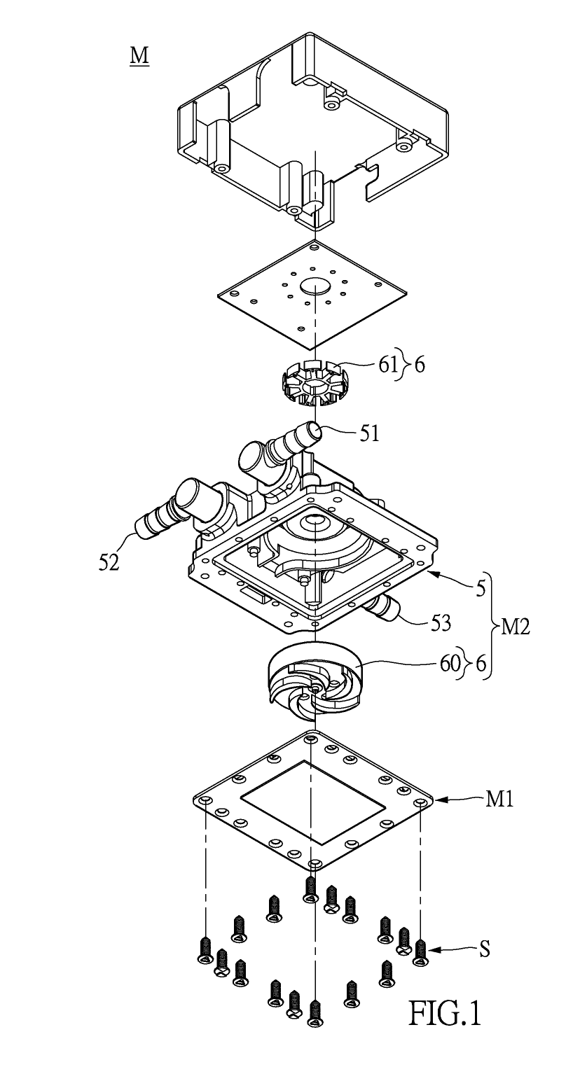

Referring to FIG. 1 to FIG. 7, the instant disclosure provides a liquid cooling heat dissipation structure M, comprising a single heat conduction module M1 and an assembly liquid supply module M2.

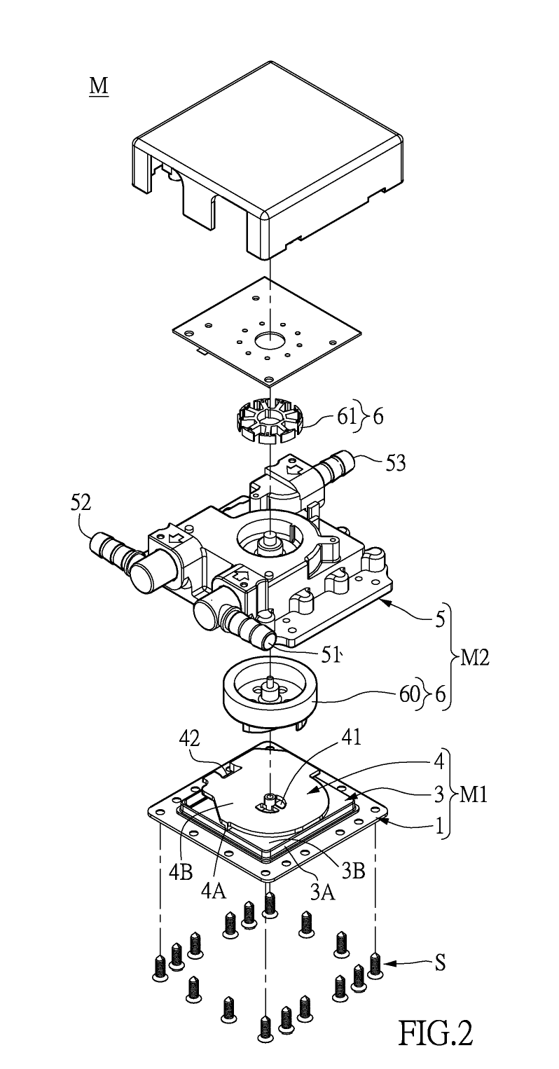

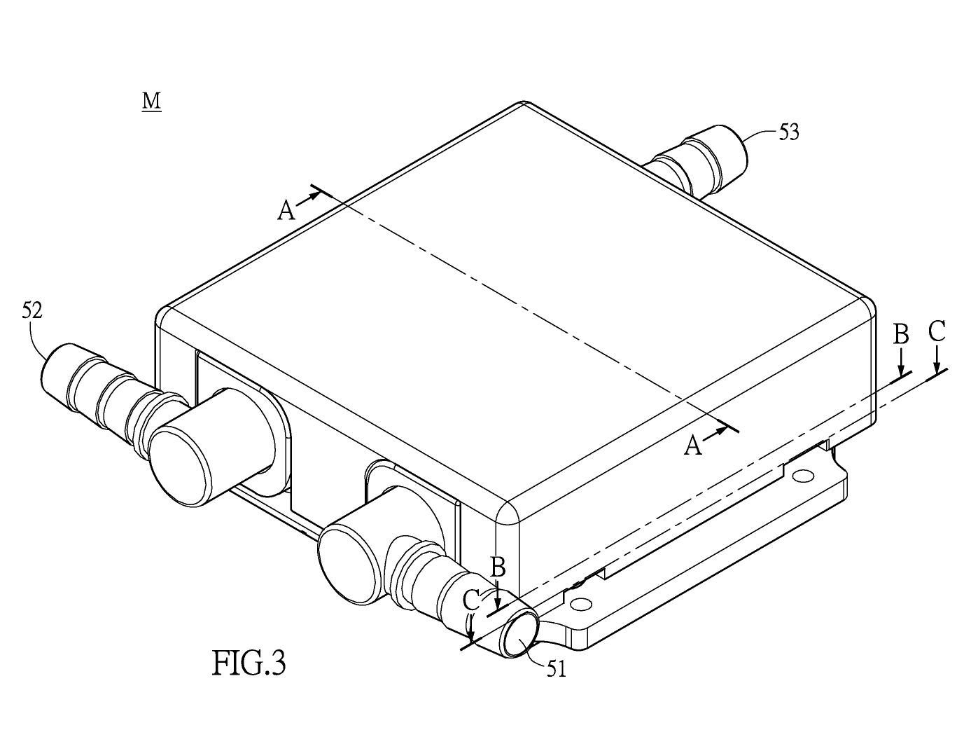

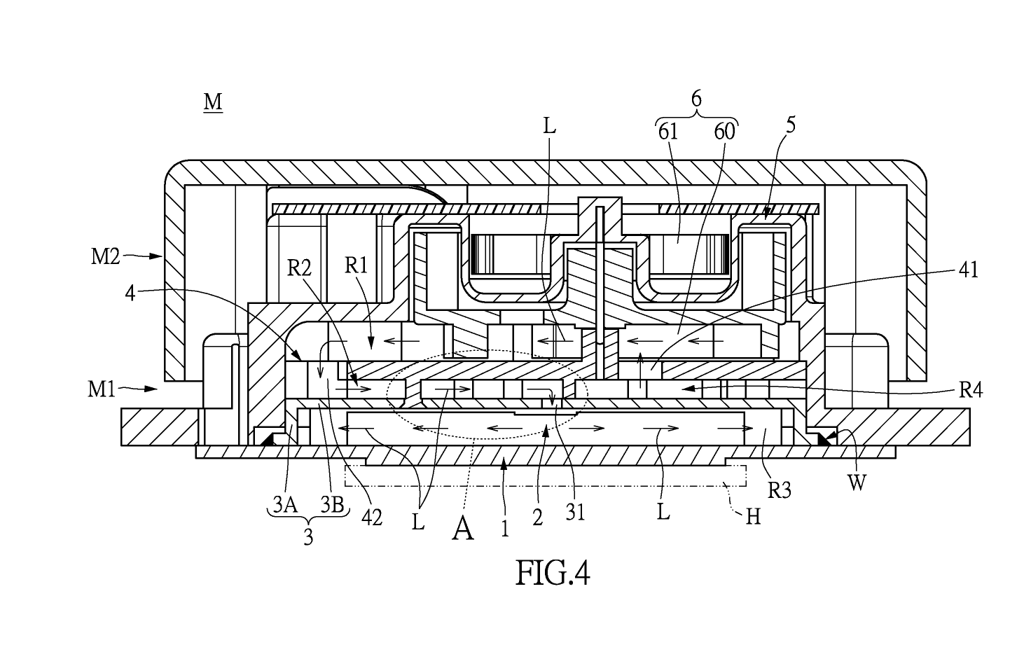

First, referring to FIG. 2, FIG. 3, and FIG. 4, the single heat conduction module M1 includes a heat-conducting substrate 1 contacting a heat generation source H (such as a CPU chip or any heat-generating chip), a plurality of heat-conducting fins 2 fixedly disposed on the heat-conducting substrate 1, a heat-conducting fluid-splitting board 3 fixedly disposed on the heat-conducting substrate 1 to cover the heat-conducting fins 2, and a heat-conducting fluid-conducting board 4 fixedly disposed on the heat-conducting fluid-splitting board 3. In addition, the assembly liquid supply module M2 includes an external cover body 5 detachably disposed on the heat-conducting substrate 1 and a pump 6 detachably disposed on the external cover body 5. All of the heat-conducting fins 2, the heat-conducting fluid-splitting board 3, and the heat-conducting fluid-conducting board 4 are received inside the external cover body 5. For example, the external cover body 5 is detachably disposed on the heat-conducting substrate 1 through bolts (screws) S, and the pump 6 includes a rotary component 60 (such as a rotor) detachably disposed between the external cover body 5 and the heat-conducting fluid-conducting board 4 and a fixing component 61 (such as a stator) corresponding to the rotary component 60.

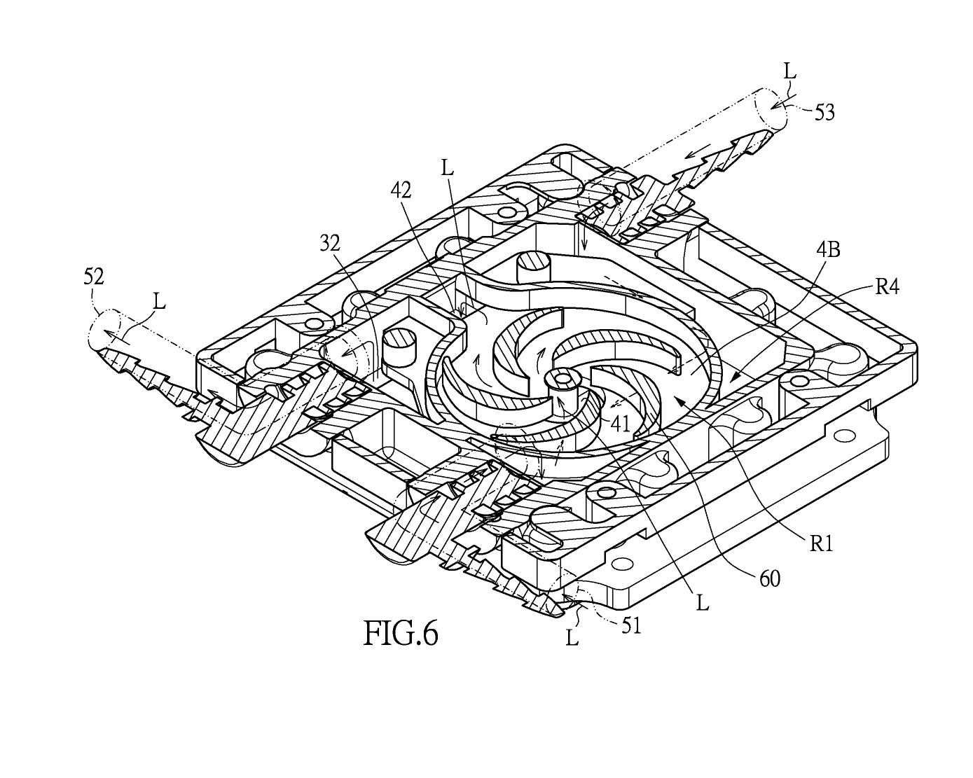

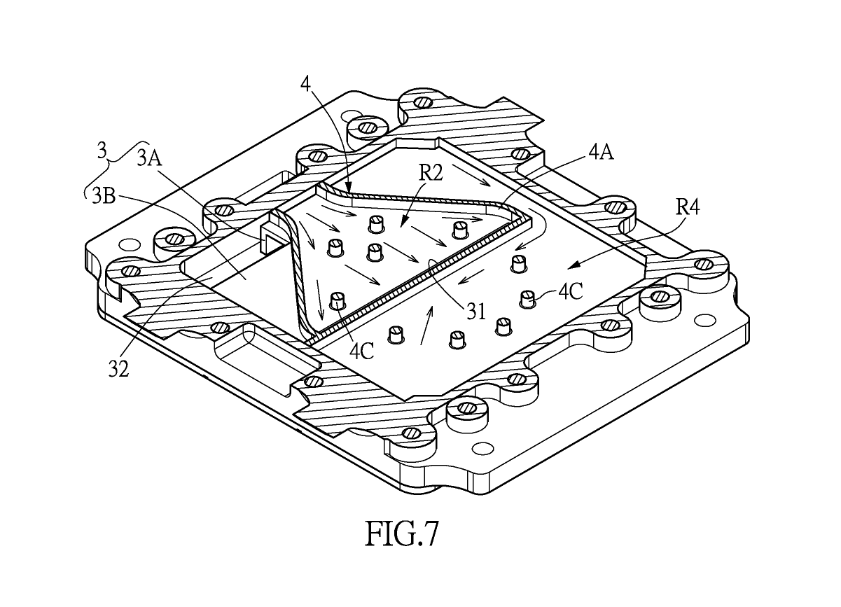

More precisely, referring to FIG. 4 and FIG. 6, the heat-conducting fluid-conducting board 4 has a first fluid-conducting opening 41 and a second fluid-conducting opening 42 communicated with the first fluid-conducting opening 41 through a first receiving space R1. In addition, referring to FIG. 4 and FIG. 7, the heat-conducting fluid-splitting board 3 has a first fluid-splitting opening 31 communicated with the second fluid-conducting opening 42 through a second receiving space R2 and a second fluid-splitting opening 32 communicated with the first fluid-splitting opening 31 through a third receiving space R3. Moreover, referring to FIG. 2, FIG. 4, FIG. 6, and FIG. 7, the external cover body 5 has at least one liquid inlet 51 communicated with the first liquid-conducting opening 41 through a fourth receiving space R4 and at least one liquid outlet 52 communicated with the second fluid-splitting opening 32. It is worth noting that the external cover body 5 may further includes another liquid inlet 53, so that the instant disclosure can use a plurality of liquid cooling heat dissipation structures M connected with each other in series and/or in parallel through the liquid inlets 53 of the liquid cooling heat dissipation structures M.

For example, referring to FIG. 2, FIG. 4, and FIG. 7, the heat-conducting fluid-splitting board 3 has a first surrounding partition portion (wall portion) 3A disposed on the heat-conducting substrate 1 to surround the heat-conducting fins 2 and a first cover plate portion 3B connected to the first surrounding partition portion 3A and disposed above the heat-conducting fins 2. In addition, the first fluid-splitting opening 31 can pass through the first cover plate portion 3B, and the second fluid-splitting opening 32 can pass through the first cover plate portion 3B and connect to the first surrounding partition portion 3A. It is worth noting that the heat generated by the heat generation source H can be transmitted to the first cover plate portion 3B through the first surrounding partition portion 3A. Therefore, the heat dissipation efficiency of the liquid cooling heat dissipation structure M can be increased by using the heat-conducting fluid-splitting board 3.

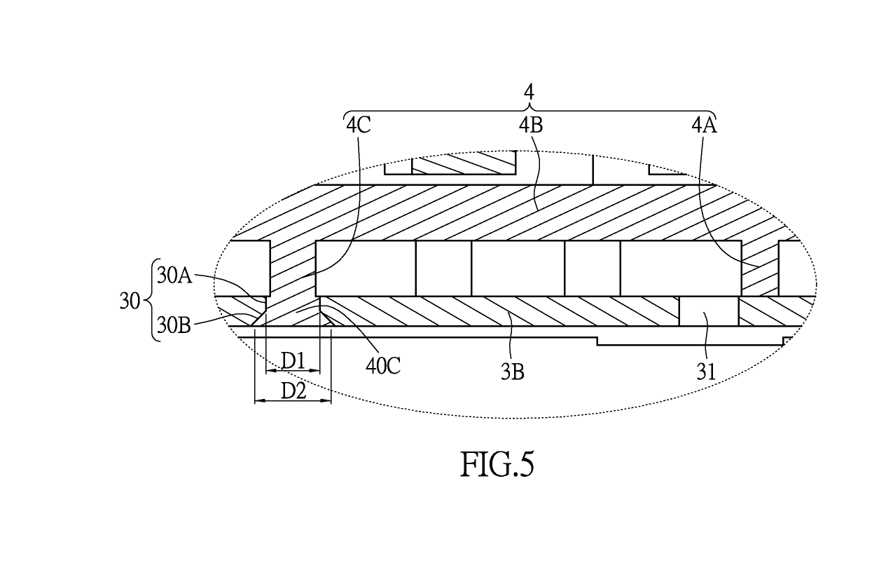

For example, referring to FIG. 2, FIG. 4, and FIG. 5, the heat-conducting fluid-conducting board 4 has a second surrounding partition portion 4A disposed on the first cover plate portion 3B, a second cover plate portion 4B connected to the second surrounding partition portion 4A and disposed above the first cover plate portion 3B, and a plurality of connection portions 4C extended downwardly from a bottom surface of the second cover plate portion 4B to the first cover plate portion 3B, and both the first fluid-conducting opening 41 and the second fluid-conducting opening 42 can pass through the second cover plate portion 4B and connect to the second surrounding partition portion 4A. It is worth noting that the heat can be transmitted from the first cover plate portion 3B to the second cover plate portion 4B through the second surrounding partition portion 4A and the connection portions 4C. Therefore, the heat dissipation efficiency of the liquid cooling heat dissipation structure M can be increased by using the heat-conducting fluid-conducting board 4.

It is worth mentioning that referring to FIG. 4, FIG. 6, and FIG. 7, the first receiving space R1 is formed between the external cover body 5 and the second cover plate portion 4B, both the second receiving space R2 and the fourth receiving space R4 are formed between the heat-conducting fluid-conducting board 4 and the first cover plate portion 3B, and the third receiving space R3 is formed between the heat-conducting fluid-splitting board 3 and the heat-conducting substrate 1. In addition, referring to FIG. 4 and FIG. 7, the second receiving space R2 and the fourth receiving space R4 are separated and isolated from each other through the second surrounding partition portion 4A, some of the connection portions 4C are disposed inside the second receiving space R2, and the other connection portions 4C are disposed inside the fourth receiving space R4, so that the connection portions 4C are distributed inside the second receiving space R2 and the fourth receiving space R4.

With regard to the method of connecting the connection portions 4C with the first cover plate portion 3B, for example, referring to FIG. 5, the first cover plate portion 3B has a plurality of through holes 30 (such as riveting holes), and each of the through holes 30 has a first through hole portion 30A connected to the second receiving space R2 or the fourth receiving space R4 and a second through hole portion 30B connected between the first through hole portion 30A and the third receiving space R3. It is worth noting that the first through hole portions 30A of the through holes 30 have the same first diameters D1, and each second through holes portion 30B has a second diameter D2 increased gradually along a direction from the first through hole portion 30A to the third receiving space R3, and each connection portion 4C has an embedded portion 40C embedded in the corresponding through hole 30. Therefore, the embedded portion 40C of each connection portion 4C can be firmly retained in the corresponding through hole 30 so as to increase the assembly robustness of the heat-conducting fluid-conducting board 4 disposed on the first cover plate portion 3B.

In conclusion, referring to FIG. 4, FIG. 6, and FIG. 7, when heat generated by the heat generation source H is transmitted to the heat-conducting substrate 1, the heat-conducting fins 2, the heat-conducting fluid-splitting board 3, and the heat-conducting fluid-conducting board 4 of the single heat conduction module M1, cooling liquid L can pass through the at least one liquid inlet 51 and flow into the external cover body 5 so as to directly contact the heat-conducting substrate 1, the heat-conducting fins 2, the heat-conducting fluid-splitting board 3, and the heat-conducting fluid-conducting board 4 by driving the rotary component 60 of the pump 6, so that the heat that has been transmitted to the heat-conducting substrate 1, the heat-conducting fins 2, the heat-conducting fluid-splitting board 3, and the heat-conducting fluid-conducting board 4 of the single heat conduction module M1 is absorbed by the cooling liquid L. Therefore, the heat dissipation efficiency of the liquid cooling heat dissipation structure M can be increased by using all of the heat-conducting substrate 1, the heat-conducting fins 2, the heat-conducting fluid-splitting board 3, and the heat-conducting fluid-conducting board 4.

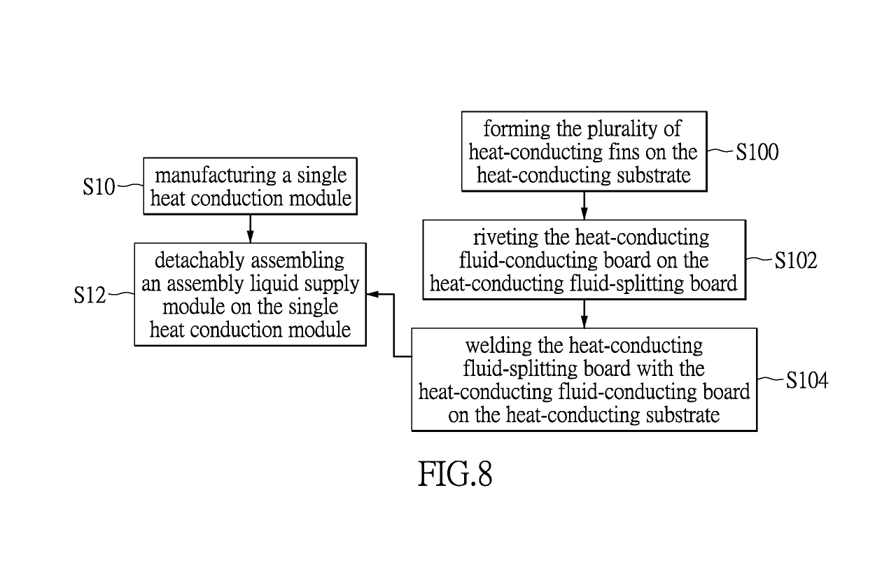

It is worth mentioning that referring to FIG. 2, FIG. 3, and FIG. 8, the instant disclosure further provides a method of manufacturing a liquid cooling heat dissipation structure M, comprising: manufacturing a single heat conduction module M1 (S10), wherein the single heat conduction module M1 includes a heat-conducting substrate 1 contacting a heat generation source H, a plurality of heat-conducting fins 2 fixedly disposed on the heat-conducting substrate 1, a heat-conducting fluid-splitting board 3 fixedly disposed on the heat-conducting substrate 1 to cover the heat-conducting fins 2, and a heat-conducting fluid-conducting board 4 fixedly disposed on the heat-conducting fluid-splitting board 3; and then detachably assembling an assembly liquid supply module M2 on the single heat conduction module M1 (S12), wherein the assembly liquid supply module M2 includes an external cover body 5 detachably disposed on the heat-conducting substrate 1 and a rotary component 60 detachably disposed between the external cover body 5 and the heat-conducting fluid-conducting board 4, wherein the heat-conducting fins 2, the heat-conducting fluid-splitting board 3, and the heat-conducting fluid-conducting board 4 are received inside the external cover body 5, and the external cover body 5 has at least one liquid inlet 51 and at least one liquid outlet 52. Hence, cooling liquid L can pass through the at least one liquid inlet 51 and flow into the external cover body 5 to directly contact the single heat conduction module M1 by driving the rotary component 60, so that heat transmitted from the heat generation source H to the single heat conduction module M1 is absorbed by the cooling liquid L.

For example, as shown in FIG. 8, the step S10 of manufacturing the single heat conduction module M1 further comprises: forming the plurality of heat-conducting fins 2 on the heat-conducting substrate 1 (S100); next, riveting the heat-conducting fluid-conducting board 4 on the heat-conducting fluid-splitting board 3 (S102), wherein the heat-conducting fluid-splitting board 3 has a plurality of riveting holes (i.e., the through holes 30); and then welding the heat-conducting fluid-splitting board 3 with the heat-conducting fluid-conducting board 4 on the heat-conducting substrate 1 (S104), wherein a surrounding welding layer W is formed between the heat-conducting fluid-splitting board 3 and the heat-conducting substrate 1. It is worth mentioning that the heat-conducting substrate 1 may be made of a first predetermined heat-conducting material by extrusion molding, and the first predetermined heat-conducting material may be one of copper, aluminum, and graphite according to different requirements. The heat-conducting fins 2 may be formed on the heat-conducting substrate 1 by planning or skiving. In addition, the heat-conducting fluid-splitting board 3 may be made of a second predetermined heat-conducting material by stamping, and the second predetermined heat-conducting material may be one of copper, aluminum, and graphite according to different requirements. Furthermore, the heat-conducting fluid-conducting board 4 may be made of a third predetermined heat-conducting material by die casting, and the third predetermined heat-conducting material may be one of copper, aluminum, and graphite according to different requirements.

However, the aforementioned design for the single heat conduction module M1 is merely an example and is not meant to limit the instant disclosure. For example, the single heat conduction module M1 may be integrally made of a predetermined heat-conducting material, and the predetermined heat-conducting material may be one of copper, aluminum, and graphite according to different requirements.

In conclusion, when heat generated by the heat generation source H is transmitted to the heat-conducting substrate 1, the heat-conducting fins 2, the heat-conducting fluid-splitting board 3, and the heat-conducting fluid-conducting board 4 of the single heat conduction module M1, cooling liquid L can pass through the at least one liquid inlet 51 and flow into the external cover body 5 so as to directly contact the heat-conducting substrate 1, the heat-conducting fins 2, the heat-conducting fluid-splitting board 3, and the heat-conducting fluid-conducting board 4 by driving the rotary component 60 of the pump 6, so that the heat that has been transmitted to the heat-conducting substrate 1, the heat-conducting fins 2, the heat-conducting fluid-splitting board 3, and the heat-conducting fluid-conducting board 4 of the single heat conduction module M1 is absorbed by the cooling liquid L so as to increase the heat dissipation efficiency of the liquid cooling heat dissipation structure M.

The aforementioned descriptions merely represent the preferred embodiments of the instant disclosure, without any intention to limit the scope of the instant disclosure which is fully described only within the following claims. Various equivalent changes, alterations or modifications based on the claims of the instant disclosure are all, consequently, viewed as being embraced by the scope of the instant disclosure.

What is claimed is:

1. A liquid cooling heat dissipation structure, comprising:
a single heat conduction module including a heat-conducting substrate contacting a heat generation source, a plurality of heat-conducting fins fixedly disposed on the heat-conducting substrate, a heat-conducting fluid-splitting board fixedly disposed on the heat-conducting substrate to cover the heat-conducting fins, and a heat-conducting fluid-conducting board fixedly disposed on the heat-conducting fluid-splitting board, wherein the heat-conducting fluid-splitting board has a first fluid-conducting opening and a second fluid-conducting opening communicated with the first fluid-conducting opening through a first receiving space, and the heat-conducting fluid-splitting board has a first fluid-splitting opening communicated with the second fluid-conducting opening through a second receiving space and a second fluid-splitting opening communicated with the first fluid-splitting opening through a third receiving space; and
an assembly liquid supply module including an external cover body detachably disposed on the heat-conducting substrate and a pump detachably disposed on the external cover body, wherein the heat-conducting fins, the heat-conducting fluid-splitting board, and the heat-conducting fluid-conducting board are received inside the external cover body, and the external cover body has at least one liquid inlet communicated with the first liquid-conducting opening through a fourth receiving space and at least one liquid outlet communicated with the second fluid-splitting opening;
wherein heat generated by the heat generation source is transmitted to the heat-conducting substrate, the heat-conducting fins, the heat-conducting fluid-splitting board, and the heat-conducting fluid-conducting board of the single heat conduction module;
wherein cooling liquid passes through the at least one liquid inlet and flows into the external cover body to contact the heat-conducting substrate, the heat-conducting fins, the heat-conducting fluid-splitting board, and the heat-conducting fluid-conducting board by driving the pump, so that the heat that has been transmitted to the heat-conducting substrate, the heat-conducting fins, the heat-conducting fluid-splitting board, and the heat-conducting fluid-conducting board of the single heat conduction module is absorbed by the cooling liquid.

2. The liquid cooling heat dissipation structure of claim 1, wherein the heat-conducting fluid-splitting board has a first surrounding partition portion disposed on the heat-conducting substrate and a first cover plate portion connected to the first surrounding partition portion and disposed above the heat-conducting fins.

3. The liquid cooling heat dissipation structure of claim 2, wherein the first fluid-splitting opening passes through the first cover plate portion, the second fluid-splitting opening passes through the first cover plate portion and is connected to the first surrounding partition portion, and the heat generated by the heat generation source is transmitted to the first cover plate portion through the first surrounding partition portion.

4. The liquid cooling heat dissipation structure of claim 2, wherein the heat-conducting fluid-conducting board has a second surrounding partition portion disposed on the first cover plate portion, a second cover plate portion connected to the second surrounding partition portion and disposed above the first cover plate portion, and a plurality of connection portions extended downwardly from a bottom surface of the second cover plate portion to the first cover plate portion.

5. The liquid cooling heat dissipation structure of claim 4, wherein both the first fluid-conducting opening and the second fluid-conducting opening pass through the second cover plate portion and is connected to the second surrounding partition portion, and the heat is transmitted from the first cover plate portion to the second cover plate portion through the second surrounding partition portion and the connection portions.

6. The liquid cooling heat dissipation structure of claim 4, wherein the first receiving space is formed between the external cover body and the second cover plate portion, both the second receiving space and the fourth receiving space are formed between the heat-conducting fluid-conducting board and the first cover plate portion, and the third receiving space is formed between the heat-conducting fluid-splitting board and the heat-conducting substrate, wherein the second receiving space and the fourth receiving space are isolated from each other through the second surrounding partition portion, some of the connection portions are disposed inside the second receiving space, and the other connection portions are disposed inside the fourth receiving space.

7. The liquid cooling heat dissipation structure of claim 6, wherein the first cover plate portion has a plurality of through holes, and each of the through holes has a first through hole portion connected to the second receiving space or the fourth receiving space and a second through hole portion connected between the first through hole portion and the third receiving space, wherein the first through hole portions of the through holes have the same first diameters, and each second through holes portion has a second diameter increased gradually along a direction from the first through hole portion to the third receiving space.

8. The liquid cooling heat dissipation structure of claim 7, wherein each connection portion has an embedded portion embedded in the corresponding through hole.

9. A liquid cooling heat dissipation structure, comprising:
a single heat conduction module including a heat-conducting substrate contacting a heat generation source, a plurality of heat-conducting fins fixedly disposed on the heat-conducting substrate, a heat-conducting fluid-splitting board fixedly disposed on the heat-conducting substrate to cover the heat-conducting fins, and a heat-conducting fluid-conducting board fixedly disposed on the heat-conducting fluid-splitting board; and
an assembly liquid supply module including an external cover body detachably disposed on the heat-conducting substrate and a rotary component detachably disposed between the external cover body and the heat-conducting fluid-conducting board, wherein the heat-conducting fins, the heat-conducting fluid-splitting board, and the heat-conducting fluid-conducting board are received inside the external cover body, and the external cover body has at least one liquid inlet and at least one liquid outlet;
wherein cooling liquid passes through the at least one liquid inlet and flows into the external cover body to contact the single heat conduction module by driving the rotary component, so that heat transmitted from the heat generation source to the single heat conduction module is absorbed by the cooling liquid.

10. The liquid cooling heat dissipation structure of claim 9, wherein the heat-conducting fluid-splitting board has a first surrounding partition portion disposed on the heat-conducting substrate and a first cover plate portion connected to the first surrounding partition portion and disposed above the heat-conducting fins, and the heat generated by the heat generation source is transmitted to the first cover plate portion through the first surrounding partition portion.

11. The liquid cooling heat dissipation structure of claim 10, wherein the heat-conducting fluid-conducting board has a second surrounding partition portion disposed on the first cover plate portion, a second cover plate portion connected to the second surrounding partition portion and disposed above the first cover plate portion, and a plurality of connection portions extended downwardly from a bottom surface of the second cover plate portion to the first cover plate portion, and the heat is transmitted from the first cover plate portion to the second cover plate portion through the second surrounding partition portion and the connection portions.

12. The liquid cooling heat dissipation structure of claim 11, wherein the first cover plate portion has a plurality of through holes, and each connection portion has an embedded portion embedded in the corresponding through hole.

13. A method of manufacturing a liquid cooling heat dissipation structure, comprising:
manufacturing a single heat conduction module, wherein the single heat conduction module includes a heat-conducting substrate contacting a heat generation source, a plurality of heat-conducting fins fixedly disposed on the heat-conducting substrate, a heat-conducting fluid-splitting board fixedly disposed on the heat-conducting substrate to cover the heat-conducting fins, and a heat-conducting fluid-conducting board fixedly disposed on the heat-conducting fluid-splitting board; and
detachably assembling an assembly liquid supply module on the single heat conduction module, wherein the assembly liquid supply module includes an external cover body detachably disposed on the heat-conducting substrate and a rotary component detachably disposed between the external cover body and the heat-conducting fluid-conducting board, wherein the heat-conducting fins, the heat-conducting fluid-splitting board, and the heat-conducting fluid-conducting board are received inside the external cover body, and the external cover body has at least one liquid inlet and at least one liquid outlet;
wherein cooling liquid passes through the at least one liquid inlet and flows into the external cover body to contact the single heat conduction module by driving the rotary component, so that heat transmitted from the heat generation source to the single heat conduction module is absorbed by the cooling liquid.

14. The method of claim 13, wherein the step of manufacturing the single heat conduction module further comprises:
forming the plurality of heat-conducting fins on the heat-conducting substrate;
riveting the heat-conducting fluid-conducting board on the heat-conducting fluid-splitting board, wherein the heat-conducting fluid-splitting board has a plurality of riveting holes; and
welding the heat-conducting fluid-splitting board with the heat-conducting fluid-conducting board on the heat-conducting substrate, wherein a surrounding welding layer is formed between the heat-conducting fluid-splitting board and the heat-conducting substrate.

15. The method of claim 13, wherein the heat-conducting substrate is made of a first predetermined heat-conducting material by extrusion molding, the heat-conducting fins are formed on the heat-conducting substrate by planning or skiving, the heat-conducting fluid-splitting board is made of a second predetermined heat-conducting material by stamping, and the heat-conducting fluid-conducting board is made of a third predetermined heat-conducting material by die casting.

16. The method of claim 15, wherein the first predetermined heat-conducting material is one of copper, aluminum, and graphite, the second predetermined heat-conducting material is one of copper, aluminum, and graphite, and the third predetermined heat-conducting material is one of copper, aluminum, and graphite.

17. The method of claim 13, wherein the single heat conduction module is integrally made of a predetermined heat-conducting material.

18. The method of claim 13, wherein the heat-conducting fluid-splitting board has a first surrounding partition portion disposed on the heat-conducting substrate and a first cover plate portion connected to the first surrounding partition portion and disposed above the heat-conducting fins, and the heat generated by the heat generation source is transmitted to the first cover plate portion through the first surrounding partition portion.

19. The method of claim 18, wherein the heat-conducting fluid-conducting board has a second surrounding partition portion disposed on the first cover plate portion, a second cover plate portion connected to the second surrounding partition portion and disposed above the first cover plate portion, and a plurality of connection portions extended downwardly from a bottom surface of the second cover plate portion to the first cover plate portion, and the heat is transmitted from the first cover plate portion to the second cover plate portion through the second surrounding partition portion and the connection portions.

20. The method of claim 19, wherein the first cover plate portion has a plurality of through holes, and each connection portion has an embedded portion embedded in the corresponding through hole.
